(19) United States
(12) Patent Application Publication
(10) Pub. No.: US 2006/0222790 A1
(43) Pub. Date: Oct. 5, 2006

(54) Preparation of library that includes monodisperse nanoclusters

(75) Inventor: Bobbi J. Roop, Los Alamos, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: The Regents of the University of California

(21) Appl. No.: 11/444,573

(22) Filed: May 31, 2006

Related U.S. Application Data
(63) Continuation-in-part of application No. 11/110,252, filed on Apr. 19, 2005, now Pat. No. 7,060,641.
(63) Continuation-in-part of application No. 10/630,447, filed on Jul. 30, 2003.

(51) Int. Cl. B31B 45/00; C23C 16/00

(52) U.S. Cl. 428/34.1; 427/248.1

(57) ABSTRACT

A library that comprises nanoclusters is prepared by generating nanocluster ions, mass selecting a predetermined monodisperse subset of these nanocluster ions, and depositing a plurality of them in cavities of a substrate. Members of the library may include monodisperse nanoclusters and other materials. After deposition, cavity walls may be removed.

### RELATED APPLICATIONS

This application is a continuation-in-part of copending U.S. patent application Ser. No. 10/630,447 filed Jul. 30, 2003, incorporated by reference herein.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates generally to combinatorial libraries and more particularly to preparing a library of samples that include monodisperse nanoclusters.

### BACKGROUND OF THE INVENTION

An important challenge in nanotechnology relates to the systematic study of nanoclusters and materials composed of nanoclusters. A nanocluster is a group of atoms that are attached together to form a nanosized (i.e. dimensions of less than a micron) cluster. Nanoclusters may vary in their chemical composition, size, and/or morphology (i.e. shape), and these parameters can have a tremendous effect on the physical and chemical properties of individual nanoclusters (see for example, U. Heiz, F. Vanolli, A. Sanchez, and W.-D Schneider, “Size-Dependent Molecular Dissociation on Mass-Selected, Supported Metal Clusters, J. Am. Chem. Soc., vol. 120, pp. 9668-9671, 1998). Therefore, part of the challenge is related to developing methods for synthesizing samples that includes nanoclusters that are monodisperse (also referred to in the art as “monodispersed”) in chemical composition, size and/or morphology (see for example: U. Heiz, F. Vanolli, L. Trento, and W.-D. Schneider, “Chemical Reactivity of Size-Selected Supported Clusters: An Experimental Setup, Rev. Sci. Instrum., vol. 68, no. 5, pp. 1986-1994, May 1997; and Stéphane Abbet, Ken Judai, Laurent Klinger, and Ueli Heiz, “Synthesis of Monodispersed Model Catalysts Using Softlanding Cluster Deposition,” Pure Appl. Chem., vol. 74, no. 9, pp. 1527-1535, 2002, both incorporated by reference herein). If a monodisperse sample of nickel that contains only, or mostly, nanoclusters of 15 atoms of nickel (Ni₁₅) having the same size and morphology can be prepared, and another monodisperse sample can be prepared that contains only, or mostly, nanoclusters of 30 atoms of nickel (Ni₃₀), and if the chemical and physical properties of the two monodisperse samples can be measured and are different, then one may conclude that the difference in a particular property (catalytic reactivity, for example) between the two samples is related to the size of particular nanocluster. In another example, a comparison could be made between a monodisperse sample of nickel that contains only, or mostly, nanoclusters of 15 atoms of nickel (Ni₁₅) having a spherical morphology, for example, and another monodisperse sample with nanoclusters of only, or mostly, Ni₁₅ having a less spherical and more flat morphology.

This type of analysis can be made between samples that are monodisperse in chemical composition, size, and/or morphology. It cannot be made when the nanoclusters of the samples are not monodisperse. The reason for this is that the property being studied (magnetism, chemical reactivity, reflectivity, conductivity, for example) of a non-monodisperse sample of nanoclusters might be due to only a small fraction of the nanoclusters present in the sample (see for example: U. Heiz, F. Vanolli, L. Trento, and W.-D. Schneider, vide supra). A single sample of nanoclusters of nickel atoms might include, for example, Ni₅ (i.e. a nickel cluster with 5 atoms), Ni₈, Ni₁₅, Ni₂₄, Ni₃₇, Ni₄₆, Ni₅₂, Ni₅₇, Ni₆₃, Ni₆₇, or some other cluster. If most of the nanoclusters of the sample were of a single type, Ni₁₅ for example, then the properties of this monodisperse sample are likely representative of the nanocluster Ni₁₅. If most of the nanoclusters of the sample are not of a single type of nickel nanocluster (Ni₁₅, for example) but instead contain significant amounts of many (Ni₈, Ni₁₅, Ni₂₄, Ni₃₇, Ni₄₆, Ni₅₂, Ni₅₇, etc.) different types of nickel nanoclusters, no such conclusion may be reached.

Until recently, the study of deposited nanoclusters was rare due to the lack of appropriate cluster generating sources (see for example: U. Heiz, F. Vanolli, L. Trento, and W.-D. Schneider, vide supra; and Stéphane Abbet et al, vide supra; U.S. Pat. No. 5,874,134 to Nagaraja P. Rao et al. entitled “Production of Nanostructured Materials by Hypersonic Plasma Particle Deposition,” which issued on Feb. 23, 1999; U.S. Pat. No. 5,759,634 to Jian-Zhi Zang entitled “Jet Vapor Deposition of Nanocluster Embedded Thin Films,” which issued on Jun. 2, 1998). Nanocluster generating sources are now commercially available (for example, the NC200U Gas Condensation Nanocluster Source (a sputtering source) available from OXFORD APPLIED RESEARCH, UK). Nanocluster generating sources (plasma sources (U.S. Pat. No. 5,874,134), jet vaporization sources (U.S. Pat. No. 5,759,634), laser ablation sources, electron beam sources, etc.) may be combined with a mass selective filters (for example, the QMF200 Quadrupole Mass Filter, OXFORD APPLIED RESEARCH, UK) that screen out all but those ionized nanoclusters of a desired mass, or at least of the narrow mass range provided by the mass selective filter. Thus, with commercially available equipment, monodisperse nanoclusters have become available to many more researchers for study.

Despite this progress, the production of monodisperse nanoclusters typically involves the synthesis of a single monodisperse sample on a single substrate and analysis of the monodisperse sample. This “one sample at a time” strategy is inefficient, as has been demonstrated by the success in employing powerful combinatorial strategies that involve preparing a library of samples on a single substrate and then screening the samples of the library rapidly and efficiently (see, for example, U.S. Pat. No. 5,776,359 to Peter G. Schultz, Xiaodong Xiang, and Isy Goldwasser entitled “Giant Magnetoresistive Cobalt Oxide Compounds,” which issued on Jul. 7, 1998). In recent years, pharmaceutical companies and research institutions have used combinatorial strategies to expedite the discovery of new compounds and drugs.

A typical combinatorial strategy involves preparing an arrayed substrate having small amounts of a plurality of samples of materials (from as few as two samples to many thousands of samples). Each sample on the substrate is typically screened by a high throughput screening (HTS) method to rapidly determine which samples of the array, if any, possess a desired property (catalytic activity, sorption properties, magnetism, luminescence, and the like). Members of the array that possess the desired property can then be prepared in larger amounts for further study. The arrayed substrate is known in the art as a “library”. The combinatorial approach permits one or more libraries that contain small amounts of thousands of materials to be studied quickly and allows researchers to focus their efforts on one or more particular samples of each library that indicate a desired property after performing HTS.

There is a need for preparing libraries of monodisperse samples of nanoclusters that can be screened rapidly in order to identify those samples with desirable properties in a more efficient manner.

### SUMMARY OF THE INVENTION

In accordance with the objects and purposes of the present invention, as embodied and broadly described herein, the present invention includes a method for preparing a library of samples that include monodisperse nanoclusters on a substrate. The method includes (a) generating gas phase nanocluster ions, each gas phase nanocluster ion comprising from about 3 to about 3000 atoms; (b) mass selecting a predetermined monodisperse subset of these gas phase nanocluster ions; (c) depositing a plurality of the monodisperse mass-selected nanocluster ions on a predetermined region of a substrate, wherein the predetermined areas comprise substrate cavities, each cavity defined by cavity side walls and a cavity floor, thereby generating a sample of deposited, monodisperse nanoclusters in substrate cavities; and repeating step (b) and then step (c) for at least another monodisperse subset of nanocluster ions at a different predetermined region on the substrate, thereby generating a library of a plurality of samples of monodisperse nanoclusters on the substrate.

The invention also includes a library prepared by the above method.

### BRIEF DESCRIPTION OF THE DRAWINGS

The accompanying drawings, which are incorporated in and form a part of the specification, illustrate the embodiment(s) of the present invention and, together with the description, serve to explain the principles of the invention. In the drawings:

FIG. 1 shows a schematic representation of an apparatus of the invention;

FIG. 2a-c schematically shows how a library of monodisperse samples may be prepared by using the apparatus of FIG. 1 with a flat substrate; and

FIG. 3 schematically shows how a library of monodisperse samples may be prepared by using the apparatus of FIG. 1 with a substrate with cavities.

FIG. 4 shows a micrograph of freestanding nanostructures formed by depositing alternating layers of nickel and aluminum oxide into the cavities of a substrate, and then removing substrate walls.

### DETAILED DESCRIPTION OF THE INVENTION

The invention includes a method for preparing a library of samples that include monodisperse nanoclusters. For the purposes of the invention, the following definitions apply.

A “nanocluster” is defined as an electrically charged group of from about 3 to about 3000 atoms or as an electrically neutral group of from about 3 to about 3000 atoms when the group of atoms is in the gas phase or deposited on a substrate. The nanocluster may include one or more metals (rare earths, transition metals, alkali metals, alkaline earth metals, actinides, lanthanides, etc.), one or more nonmetals (oxygen, nitrogen, phosphorus, sulfur, and the like).

A “substrate” is defined as a support onto which nanoclusters or other materials are deposited. A support may be a substantially flat solid, or may have cavities (a template, for example) into which nanoclusters or other materials are deposited. These cavities may be filled with a liquid, gel, or other material into which the nanoclusters can be deposited such as ice, condensed argon, ionic liquids and the like. The nanoclusters may be deposited in the liquid, gel, etc. or on the surface thereof. The substrate can be a uniform material that is homogeneous throughout, or may include regions of different materials.

The term “monodispersed nanoclusters” is defined as nanoclusters having the same size, composition, and morphology.

A “monodisperse sample” is defined as a sample deposited on a substrate that includes a sufficient amount of one type of nanocluster for an observable property of the sample to be due to the presence of that nanocluster. A monodispersed sample may include one or more types of monodispersed nanoclusters.

A “monolayer” is defined as layer of one or more types of monodispersed nanoclusters and/or other material, having the maximum coverage for that combination of materials on a substrate.

A “submonolayer” is defined as a layer of one or more types of monodispersed nanoclusters and/or other material having less than the maximum coverage for that combination of materials on a substrate.

A “thin film” is defined as one or more deposited layers. These layers may be submonolayers or monolayers. For a thin film of multiple layers, the first layer is deposited on the substrate and then the next layer is deposited on the first layer, etc. A thin film may include hundreds of layers, but preferably has from about 1 to about 100 layers.

A “library” is defined as a plurality of samples that include monodisperse nanoclusters. A library may include as few as two samples of monodisperse nanoclusters, and may include many thousands of samples. Each sample is deposited on a preselected area on a substrate.

The “morphology” of the nanocluster is defined as the 3-dimensional shape of the nanocluster after it is deposited on a substrate.

A “target” is defined as a material from which a beam of electrically charged gas phase nanoclusters is produced. Every source that can be used with the invention requires a target. A target can be fabricated from metals, semiconductors, non-metals, metal alloys, ceramics, and mixtures of these materials. A target could be made from a single element such as nickel silicon, platinum, germanium, sodium, etc. A target could be made from several chemical elements such as iron oxide, cobalt sulfide, etc.). More generally, any material from which electrically charged gas phase nanoclusters can be produced that can be separated by their masses can be used as a target.

A “lens” is defined as a deflecting means for deflecting a beam of electrically charged, gas phase nanoclusters.

A “shutter” is defined as a blocking means for blocking a beam of electrically charged gas phase nanoclusters.

A “mass filter” is defined as a selecting means for selecting a monodisperse subset of electrically charged gas phase nanoclusters from the beam generated by a target.

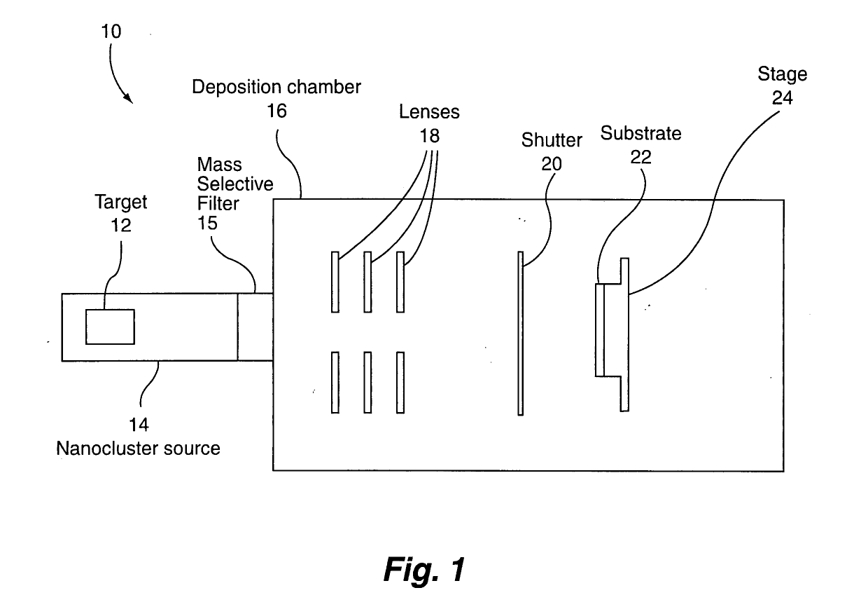

Reference will now be made in detail to the present preferred embodiments of the invention. Similar or identical structure is identified using identical callouts. A schematic view of an apparatus for preparing a library of monodisperse samples of nanoclusters is shown in FIG. 1. Apparatus 10 includes target 12 in nanocluster source 14. Target 12 provides ions that aggregate inside nanocluster source. Nanocluster ions of various sizes are formed in nanocluster source 14 after the material of interest has been vaporized from target 12. Apparatus 10 also includes a mass selective filter 15 that selects a subset of the nanocluster ions produced from source 14. Apparatus also includes deposition chamber 16, and inside the chamber are lenses 18 for controlling the direction of the nanocluster beam produced by nanocluster source 14 and target 12. Three lenses are shown in FIG. 1 for illustrative purposes only; the number and type of lenses will depend upon the properties of the beam of nanoclusters being deflected. Also inside deposition chamber 16 are shutter 20, substrate 22 onto which nanoclusters are deposited, and stage 24. Stage 24 may be adjusted by translation and/or rotation for adjusting the position of substrate 22. Apparatus 10 also includes one or more pumps and pressure gauges (not shown). The position of translation stage may be adjustable by computer-controlled means, not shown, and the computer-controlled means can also be used to adjust the lenses, shutter, tuning of the mass filter to select the subset of nanoclusters for deposition, etc.

Apparatus 10 optionally may include one or more detectors and screening devices for detecting deposition and for screening the library of samples produced according to the invention. A particular screening device used for a particular library would depend on the property being investigated (catalytic activity, optical properties, sorption properties, and the like). The types of screening units that may be used with the invention have already been described elsewhere (see, for example, U.S. Pat. No. 5,776,359, PCT Application WO 98/15805, PCT Application WO 98/15813, vide supra).

Apparatus 10 may be a subunit of a larger apparatus with additional targets, nanocluster sources, mass selective filters, lenses, shutters, etc. that provide additional beams directed at the substrate 22. In addition, other devices may be attached that are capable of depositing materials other than nanoclusters on the substrate.

Apparatus 10 may optionally include a gas introduction unit capable of introducing one or more gases (oxygen, hydrogen, nitrogen, and the like) or gas mixtures into deposition chamber 16.

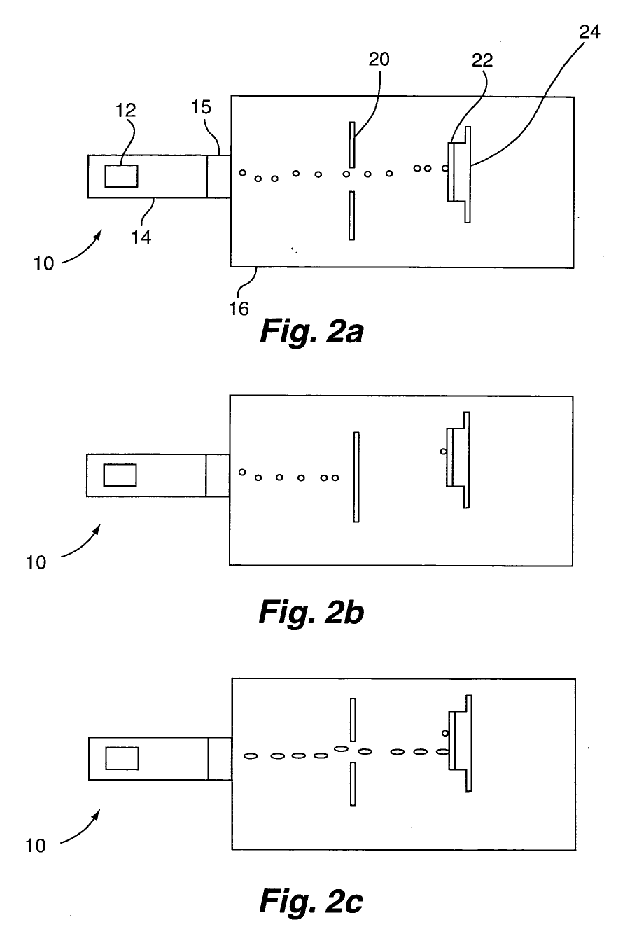

FIGS. 2a, 2b, and 2c show schematic views of the deposition of two samples of monodisperse nanoclusters. As FIG. 2a shows, the shutter is in the open position. Nanoclusters exit the mass selective device, the shutter, and then and then through the shutter and then deposit on a first predetermined area of the substrate. After a sufficient number of nanoclusters have deposited, the shutter is closed (FIG. 2b). With the shutter closed, a beam of the same type, or in this case a different type of nanocluster (these clusters are depicted in the figure as ovals) is generated and the substrate is translated so that the new beam can deposit these nanoclusters on a different predetermined area (FIG. 2b). Afterwards, the shutter is opened again (FIG. 2c) and the new beam passes through the open shutter and nanoclusters from the beam deposit on a different predetermined area. Lenses 18 are omitted from FIG. 2a-c to indicate that the nanocluster ions are directed to a predetermined area by moving the translation stage. It should be understood that the library of the invention can be made by using both lenses 18 and translation stage 24. When a sufficient number of nanoclusters from this beam have deposited, shutter 20 may be closed again and the procedure repeated until the desired library is prepared.

Different substrates can be used with the invention. The substrate composition may have an effect on the chemical and/or physical properties of the deposited nanoclusters. The preparation of a library of samples of monodisperse nanoclusters on a first substrate (silicon, for example) and a library of identical samples of monodisperse nanoclusters on a different substrate (titanium, for example) provides a means for studying any effects the substrate may have on the chemical and physical properties of the deposited samples of monodisperse nanoclusters.

According to one aspect of the invention, a library of samples may be prepared where each sample includes nanoclusters that are monodisperse in chemical composition, size, and morphology. An apparatus for preparing such a sample includes a nanocluster source in combination with a mass selective filter that screens out all but those nanoclusters of a desired mass, or at least provides a narrow mass range limited by the resolution of the mass selective filter. The NC200U Gas Condensation Nanocluster Source available from OXFORD APPLIED RESEARCH, UK may be used as a nanocluster source with the invention. It should be understood that other types of sources can also be used, such as the sources described in U.S. Pat. No. 5,874,134, jet vaporization sources such as the one described in U.S. Pat. No. 5,759,634, laser ablation sources, electron beam sources, and the like. Any of these sources includes a target that produces nanoclusters by vaporizing the target. An example of a commercially available mass selective filter that can be used with the invention is the QMF200 Quadrupole Mass Filter available from OXFORD APPLIED RESEARCH, UK. It should be understood that the invention is not limited to commercially available filters, and that any filter capable of mass selecting a desired subset of nanoclusters produced by the source can be used.

According to another aspect of the invention, each sample of monodisperse nanoclusters is deposited from a nanocluster beam to a different region on a substrate. This may be accomplished by the use of a movable stage that moves the substrate to a desired location, and/or by steering the beam by adjusting the voltages of lenses positioned along the beam path or by using a mask. The use of lenses to steer the beam is possible because the nanoclusters in the beam are ions that respond to voltage changes produced by the lenses.

To prepare the nanoclusters, a target is used that is composed of the elements of the desired nanoclusters. If nanoclusters of nickel are desired, for example, then a target made of nickel is used. Similarly, if nanoclusters of more than one metal (nickel and iron, for example) are desired, then the appropriate target (nickel and iron) may be used. Vaporization of the target to provide nanoclusters can occur by electron beam or ion sputtering, plasma discharge, or laser ablation techniques or other vaporization techniques. Some of the nanoclusters are ionized during formation so nanoclusters can be selected for size and, therefore, also for composition using a mass filter.

A nanocluster source (the NC200U Gas Condensation Nanocluster Source, for example) used for preparing nanocluster ions in the gas phase includes an aggregation chamber where the nanoclusters form. A mass selective filter (the QMF200 Quadrupole Mass Filter, for example) is able to select a subset of nanoclusters of a specific mass made from the nanocluster source for deposition. If a nickel target is selected, for example, nickel nanoclusters are generated. Of these nickel nanoclusters, a choice is made to deposit a subset of these nanoclusters (Ni₃₀, for example) and the mass selective filter is adjusted to filter all but Ni₃₀ nanoclusters. It should be understood that in practice, however, there are limits to the resolution of mass selective filters and that in all cases minor amounts nanoclusters other than the desired nanocluster are also present in the beam emitted by the mass selective filter. The beam, which in this exemplary case includes a majority of Ni₃₀ nanoclusters, is directed at a predetermined area on the substrate, and the nanoclusters in the beam are deposited on the predetermined area. After deposition, a shutter device or other means for blocking the beam (such as detuning the mass filter) is used to prevent the beam from depositing additional nanoclusters as the substrate is translated to a new position. In the meantime, the mass selective filter is readjusted for a different nanocluster (Ni₂₅, for example). After this readjustment and repositioning of the substrate, the shutter device is adjusted so that the beam now can pass to the substrate and the beam of mostly Ni₂₅ nanoclusters is directed at a different predetermined area of the substrate. This procedure can be repeated to generate a library of samples of monodisperse nanoclusters. The beam can be allowed to deposit a submonolayer, a monolayer, a multilayer thin film, etc., depending on the flux and the amount of time allowed for deposition.

The combination of nanocluster source and mass selective filter can select the size and composition of nanoclusters consisting of a few atoms to nanoclusters containing thousands of atoms.

Nanoclusters of metals, non-metals, and semiconductors may be produced, and available nanoclusters are limited only by the availability of targets that can be vaporized to produce the nanoclusters, and a wide selection of targets can be fabricated using established methods (sintering, for example). Powders of Ni and Pt can be mixed and sintered to produce a target to form Ni, Pt, and Ni/Pt nanoclusters. Powders of main group elements such as B and C can be mixed and sintered to produce targets for formation of B, C and B/C nanoparticles. Single element targets, as well as binary, ternary, quaternary, etc targets may be composed from transition metals, main group elements, actinides, lanthanides or any combinations of these. Segmented targets having different regions of a target made of different materials can be used. As a result, monodisperse nanoclusters composed of different material can be made. For example, monodisperse samples of Pt₃₅Ni₁₅ can be made.

The distances between the predetermined regions on the substrate can vary (nanometers, microns, millimeters, etc.) and will depend on the technique chosen for screening the samples (infrared spectroscopy, ultraviolet spectroscopy, visible spectroscopy, x-ray photoemission spectroscopy, thermal desorption spectroscopy, etc.) and by the resolution of the translation stage used for translating the substrate from one position to another (this resolution can also be on the order of nanometers, microns, millimeters, etc.) or by the distance the beam is steered by the lenses or by using a mask. Examples of screening apparatus that may be used for screening libraries of monodisperse samples of nanoclusters prepared according to the present can be found in U.S. Pat. No. 5,776,359 to Peter G. Schultz et al. entitled “Giant Magnetoresistive Cobalt Oxide Compounds,” which issued on Jul. 7, 1998; PCT Application WO 98/15805 to Eric W. McFarland et al. entitled “Optical Systems and Methods for Rapid Screening of Libraries of Different Materials,” which was published on Apr. 16, 1998; PCT Application WO 98/15813 to Eric W. McFarland et al. entitled “Infrared Spectroscopy and Imaging of Libraries,” which was published on Apr. 16, 1998, all hereby incorporated by reference.

Another aspect of the invention relates to the use of deflection lenses to steer the beam of nanoclusters to a predetermined region of the substrate. A target is selected, nanoclusters are generated from the target, voltages of the lenses are adjusted to direct a beam from the mass filter to a first predetermined area on the substrate, the beam is generated and the nanoclusters are deposited. After this deposition, the beam may be blocked as previously described (using the shutter or detuning the mass filter), the voltages on the lenses may be readjusted, and the beam may be steered to a different predetermined region on the substrate. The mass filter can be adjusted for the same or a different subset of nanoclusters. Also within the scope of the invention, the apparatus may include additional nanocluster sources and targets for providing additional beams, and one or more of these can be used as well for depositing nanoclusters.

Yet another aspect of the invention relates to exposing nanoclusters to reactive gases. This exposure may occur during formation of the nanoclusters, during deposition (the nanocluster ions being exposed), or after deposition on a substrate.

Yet another aspect of the invention relates to preparing monodisperse samples of multilayer thin films of nanoclusters. The preparation of a multilayer sample may involve first depositing a monolayer (or submonolayer) of monodisperse nanoclusters (Ni₃₀ for example) on a predetermined region of the substrate and then, without translating the stage or deflecting the beam, selecting a different nanocluster (Ni₂₅, for example) and depositing a monolayer (or submonolayer) of that nanocluster on the first monolayer (or submonolayer). This process can be repeated before a new region is selected. It should be understood that the choice of using a nickel target, or even a single target is only exemplary. A multilayer film prepared according to the invention may include a monodisperse layer of nanoclusters of Ni₂₅, a monodisperse layer of nanoclusters of Fe₁₆ (using an iron target) on the Ni₂₅ layer, a monodisperse layer of Na₉C₃₅ on the Fe₁₆ layer, a monodisperse layer of Co₄₂Sn₅₃W₂₄ on the Fe₁₆ layer, a monodisperse layer of Ti₁₂ on the Co₄₂ layer, a monodisperse layer of W₁₇ on the Ti₁₂ layer, a monodisperse layer of Sn₁₄ may be deposited on the W₁₇, a monodispersed layer of Pt₁₂Fe₃₀ on the layer of W₁₇, and so on. It should be understood that the above compositions are only exemplary.

For a type of catalytic study, for example, it might be important to prepare a library of nanoclusters that are composed of more than one element (Pt and Sn, for example). A Pt/Sn target (a segmented target of Pt and Sn, for example, or separate targets of Pt and Sn could be used. During aggregation, many different nanoclusters that contain Pt and Sn would form. A library of monodisperse nanoparticles could be prepared by using the mass filter to selectively screen out all nanoclusters except for, for example, Pt₂₅Sn₉, so that a monolayer of this nanocluster could be deposited on a first predetermined region of a substrate. After deposition of this composition, then monodisperse nanoclusters of Pt₃₀Sn₇ could be deposited on a second predetermined region (or even on the layer of Pt₂₅Sn₉, if desired). Afterwards, a different monodisperse layer could be deposited on a third region.

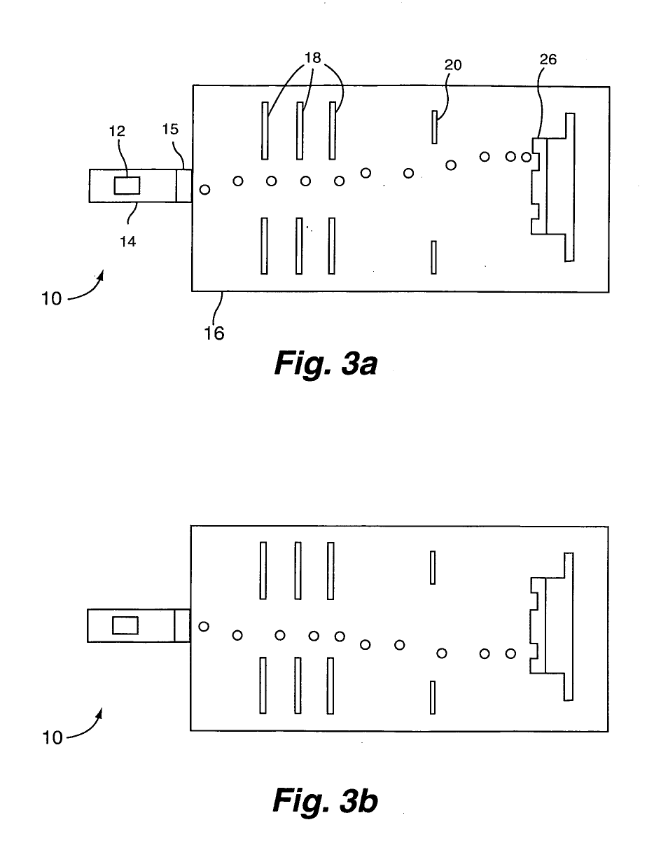

Still another aspect of the invention relates to the use of substrates with cavities. FIGS. 3a and 3b show schematically how deposition of monodisperse nanoclusters may occur. FIG. 3a shows a beam of nanocluster ions being deflected so that the beam forms a deposit of monodisperse nanoclusters in a substrate 26 cavity, and FIG. 3b shows another beam of nanoclusters being deflected so that the beam deposits nanoclusters in a different substrate cavity. Substrates with cavities (templates, for example) are particularly useful for preparing thin films of monodisperse nanoclusters. Each substrate cavity is defined by walls, which can be removed without damaging the thin film. The procedure for removing the cavity walls would depend on the choice of substrate material used.

Substrates with cavities filled with a gel, liquid, or other material may be used with the invention. Each preselected area on the substrate may be a gel-filled or liquid (ionic liquid, for example) filled cavity. Liquids can be solvents for the nanoclusters, and may contain one or more ligands that form complexes with the nanoclusters. The choice of liquid may depend on factors such as pH, viscosity, and other properties of the liquid. Room temperature ionic liquids can be used. If the substrate is cooled sufficiently, materials such as ice or even condensed argon are contemplated as substrate materials, or in substrate cavities.

The energy of the nanocluster beam may be adjusted during the deposition process with the lenses, carrier gases, or by changing the temperature of the substrate. Changes in the beam energy and substrate temperature are expected to affect the morphology of the deposited nanoclusters. To minimize the likelihood of producing nanoclusters that vary in morphology in a sample, the substrate temperature and beam energy during deposition of a sample may be constant during the deposition of that sample.

Another aspect of the invention relates to the deposition of materials that are not necessarily monodisperse nanoclusters on already deposited monodisperse nanoclusters. After deposition of a monodisperse layer of metal nanoclusters (Fe₃₀, for example) a layer of metal oxide, for example (iron oxide for example) may be deposited on the Fe₃₀ layer. This layer could be deposited by removing substrate 22 or 26 from apparatus 10 and using a different apparatus or method to deposit the metal oxide (or other material). Afterward, substrate 22 could be remounted on translation stage 24 for additional deposition steps, if desired. Alternatively, apparatus 10 may be a part of a larger apparatus that includes both apparatus 10 and optional features for depositing the additional material on the nanoclusters.

The following EXAMPLE illustrates the preparation of a freestanding structure of alternating layers of nickel and aluminum oxide.

### EXAMPLE

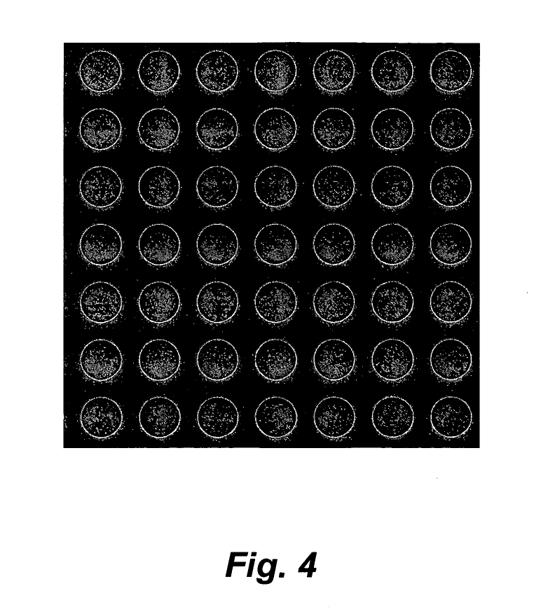

A flat piece of silicon was spin coated with a 2-micron thick layer of polymethylmethacrylate (PMMA). A mask made of chrome on soda lime was placed on the PMMA layer, and the assembly was exposed to ultraviolet light for about 7 seconds. After removing the mask, the exposed polymer was removed using a developing solution. The result was a substrate having round cavities that were 20 microns in diameter and separated from each other by a distance of about 10 microns. This substrate was used for preparing a library by filling the cavities with layered structures. Each structure was prepared by sputtering a layer of nickel into each cavity, followed by sputtering a layer of aluminum oxide onto the nickel, followed by sputtering a layer of nickel onto the aluminum oxide, etc. until a total height of about 200 nanometers was reached, where each layer had a height of about 10 nanometers. Afterward filling the cavities with the layered structures, the polymer was dissolved away using acetone. The result was freestanding nanostructures that could be included in a library. A micrograph of these structures is shown in FIG. 4.

In summary, the invention provides a method for preparing a library of samples that include monodisperse nanoclusters. The samples can be submonolayers, monolayers, and multilayer thin films. The substrates can be homogeneous or heterogeneous. While a library of the invention can include as few as two samples on a single substrate, preferably a substrate will include tens, hundreds, and perhaps thousands of samples. After the library is prepared, the samples may be screened by any of a wide variety of known screening methods (infrared spectroscopy, ultraviolet spectroscopy, visible spectroscopy, and the like).

The foregoing description of the invention has been presented for purposes of illustration and description and is not intended to be exhaustive or to limit the invention to the precise form disclosed, and obviously many modifications and variations are possible in light of the above teaching.

The embodiment(s) were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A method for preparing a library of samples that include monodisperse nanoclusters on a substrate, comprising:
(a) generating gas phase nanocluster ions, each gas phase nanocluster ion comprising from about 3 to about 3000 atoms;
(b) mass selecting a predetermined monodisperse subset of these gas phase nanocluster ions;
(c) depositing a plurality of the monodisperse mass-selected nanocluster ions on a predetermined region of a substrate, wherein the predetermined areas comprise substrate cavities, each cavity defined by cavity side walls and a cavity floor, thereby generating a sample of deposited, monodisperse nanoclusters in substrate cavities; and
(d) repeating step (b) and then step (c) for at least another monodisperse subset of nanocluster ions at a different predetermined region on the substrate, thereby generating a library of a plurality of samples of monodisperse nanoclusters on the substrate.

2. The method of claim 1, wherein each nanocluster comprises at least one main group chemical element.

3. The method of claim 1, wherein each nanocluster comprises at least one elemental metal.

4. The method of claim 1, wherein each nanocluster comprises at least one lanthanide element.

5. The method of claim 1, wherein at least one sample of deposited, monodisperse nanoclusters comprises a monolayer.

6. The method of claim 1, wherein at least one sample of deposited monodisperse nanoclusters comprises a thin film.

7. The method of claim 6, wherein the thin film comprises a plurality of monolayers in a substrate cavity.

8. The method of claim 7, further comprising the step of removing the cavity side walls after depositing the thin film inside the cavity.

9. The method of claim 1, where the substrate cavities are liquid-filled cavities.

10. The method of claim 1, further comprising depositing a material other than nanoclusters on the deposited nanoclusters.

11. A combinatorial library on a substrate with cavities, the library prepared by a process comprising:
(a) generating gas phase nanocluster ions, each gas phase nanocluster ion comprising from about 3 to about 3000 atoms;
(b) mass selecting a predetermined monodisperse subset of these gas phase nanocluster ions;
(c) depositing a plurality of the monodisperse mass-selected nanocluster ions on a predetermined region of a substrate, wherein the predetermined areas comprise substrate cavities, each cavity defined by cavity side walls and a cavity floor, thereby generating a sample of deposited, monodisperse nanoclusters in substrate cavities; and
(d) repeating step (b) and then step (c) for at least another monodisperse subset of nanocluster ions at a different predetermined region on the substrate, thereby generating a library of a plurality of samples of monodisperse nanoclusters on the substrate.

12. The library of claim 11, wherein each nanocluster comprises at least one main group chemical element.

13. The library of claim 11, wherein each nanocluster comprises at least one elemental metal.

14. The library of claim 11, wherein each nanocluster comprises at least one lanthanide element.

15. The library of claim 11, wherein at least one sample of deposited, monodisperse nanoclusters comprises a monolayer.

16. The library of claim 11, wherein at least one sample of deposited monodisperse nanoclusters comprises a thin film.

17. The library of claim 16, wherein the thin film comprises a plurality of monolayers in a substrate cavity.

18. The library of claim 17, further comprising the step of removing the cavity side walls after depositing the thin film inside the cavity.

19. The method of claim 11, where the substrate cavities are liquid-filled cavities.

20. The method of claim 11, further comprising depositing a material other than nanoclusters on the deposited nanoclusters.
